(19) United States
(12) Patent Application Publication
(10) Pub. No.: US 2025/0204257 A1
(43) Pub. Date: Jun. 19, 2025

(54) PIEZOELECTRIC ELEMENT ASSEMBLY AND METHOD FOR MANUFACTURING SAME

(71) Applicant: Suncall Corporation, Kyoto-shi, Kyoto (JP)

(72) Inventor: Satoru TAKASUGI, Kyoto-shi, Kyoto (JP)

(21) Appl. No.: 18/696,195

(22) PCT Filed: Sep. 28, 2021
(86) PCT No.: PCT/JP2021/035501

§ 371 Date: Dec. 27, 2024

(51) Int. Cl. H10N 30/073; H10N 30/063; H10N 30/067; H10N 30/87

(52) U.S. Cl. CPC H10N 30/073; H10N 30/063; H10N 30/067; H10N 30/871; H10N 30/874

(57) ABSTRACT

A piezoelectric element assembly of this invention includes a piezoelectric element with upper and lower electrodes forming an external electrode and an internal electrode, and a wiring structure including first and second wirings electrically connected to the external and internal electrodes, respectively, wherein the piezoelectric element includes lower and internal electrode terminals away from the upper electrode through lower-electrode-side and internal-electrode-side gaps, respectively. The first wiring is bonded to a first conductive bonding material integrally covering parts of the lower electrode terminal and the upper electrode. The second wiring is bonded to a second conductive bonding material covering the internal electrode terminal. An internal-electrode-terminal facing area of the upper electrode facing the internal electrode terminal through the internal-electrode-side gap is covered with an insulating film.

### FIELD OF THE INVENTION

The present invention relates to a piezoelectric element assembly including a laminated piezoelectric element and a wiring structure including first and second wirings that are electrically connected to external and internal electrodes of the piezoelectric element, respectively, and a manufacturing method of the same.

### BACKGROUND ART

As a laminated piezoelectric element, there has been proposed a piezoelectric element including: a piezoelectric element main body made of a piezoelectric material; an upper electrode and a lower electrode provided on an upper surface and a lower surface of the piezoelectric element main body, respectively; an internal electrode for dividing the piezoelectric element main body into a first piezoelectric portion on an upper side, and a second piezoelectric portion on a lower side in a thickness direction; a lower electrode connector provided on an upper surface of the piezoelectric element main body in a state that a base end thereof is electrically connected to the lower electrode, and a tip end thereof has a lower-electrode-side gap with respect to the upper electrode, and forming a lower electrode terminal; and an internal electrode connector provided on the upper surface of the piezoelectric element main body in a state that a base end thereof is electrically connected to the lower electrode, and a tip end thereof has an internal-electrode-side gap with respect to the upper electrode, and forming an internal electrode terminal (see Patent Literature 1).

The laminated piezoelectric element having a configuration as described above is useful in that electrical connection of associated wiring can be performed from an upper surface on one side in the thickness direction with respect to both of the upper electrode and the lower electrode forming an external electrode, and all of the internal electrodes.

That is, a first conductive adhesive is provided in such a way as to extend across both of the lower electrode terminal, and a lower-electrode-terminal facing area of the upper electrode facing the lower electrode terminal via or through the lower-electrode-side gap, and a first wiring associated with the first conductive adhesive is bonded, whereby electrical connection of the first wiring to both of the upper electrode and the lower electrode can be performed on an upper surface of the piezoelectric element. Further, a second conductive adhesive is provided on the internal electrode terminal, and a second wiring associated with the second conductive adhesive is bonded, whereby electrical connection of the second wiring to the internal electrode can be performed on the upper surface of the piezoelectric element.

The piezoelectric element converts a voltage applied between the external electrode and the internal electrode into a flexural vibration, or converts a vibration to be propagated into a voltage between the first and second electrodes, and in order to improve conversion efficiency between the voltage and the flexural vibration, it is necessary to increase a facing area between the upper electrode and the internal electrode, and a facing area between the internal electrode and the lower electrode as much as possible.

However, in order to increase the facing area between the upper electrode and the internal electrode as much as possible, it is necessary to increase an area of the upper electrode itself as much as possible, which causes the following problem.

That is, an increase in the area of the upper electrode leads to narrowing of the internal-electrode-side gap, and the risk of contact of the second conductive adhesive with the upper electrode increases due to a variation in the application amount and a variation in the application position of the second conductive adhesive to be applied onto the internal electrode terminal. This leads to lowering in the yield due to short-circuiting between the external electrode (the upper electrode) and the internal electrode, or lowering in the efficiency of an application operation of the second conductive adhesive.

Further, even when the second conductive adhesive does not come into contact with the upper electrode during an application operation of the second conductive adhesive, narrowing of the internal-electrode-side gap may cause ion migration under the use environmental conditions of the piezoelectric element such as high temperature and high humidity, which may lead to a short circuit failure.

### PRIOR ART DOCUMENT

### Patent Literature

Patent Literature 1: Japanese Patent No. 6776481

### SUMMARY OF THE INVENTION

The present invention has been made in consideration of the conventional technology, and it is an object to provide a piezoelectric element assembly including a laminated piezoelectric element and a wiring structure that includes wirings electrically connected to the piezoelectric element, the piezoelectric element capable of electrical connection of an external electrode including upper and lower electrodes to a corresponding wire and electrical connection of an internal electrode to a corresponding wire on an upper surface of the piezoelectric element on one side in the thickness direction of the piezoelectric element, and effectively preventing short-circuiting between the external electrode and the internal electrode while improving conversion efficiency between the voltage and the flexural vibration in the piezoelectric element, and also provide a manufacturing method of the same.

In order to achieve the object, the present invention provides a piezoelectric element assembly including a laminated piezoelectric element and a wiring structure including first and second wirings that are electrically connected to external and internal electrodes of the piezoelectric element, respectively, wherein the piezoelectric element includes a piezoelectric element main body made of a piezoelectric material, upper and lower electrodes that are arranged on upper and lower surfaces of the piezoelectric element main body, respectively and form the external electrode, an internal electrode that divides the piezoelectric element main body into upper and lower sides in the thickness direction, a lower electrode connector that has a base end side electrically connected to the lower electrode and a tip end side arranged on the upper surface of the piezoelectric element main body in a state of having a lower-electrode-side gap with respect to the upper electrode so as to form a lower electrode terminal, and an internal electrode connector that has a base end side electrically connected to the internal electrode and a tip end side arranged on the upper surface of the piezoelectric element main body in a state of having an internal-electrode-side gap with respect to the upper electrode so as to form an internal electrode terminal, wherein the first wiring is electrically connected to the lower electrode terminal and the upper electrode by a first conductive bonding material, wherein the second wiring is electrically connected to the internal electrode terminal by a second conductive boding material, and wherein an internal-electrode-terminal facing area of the upper electrode facing the internal electrode terminal via or through the internal-electrode-side gap is covered with an insulating film.

The piezoelectric element assembly in accordance with the present invention makes it possible to electrically connect the external electrode including upper and lower electrodes to a corresponding wire and also electrically connect the internal electrode to a corresponding wire on an upper surface of the piezoelectric element on one side in the thickness direction of the piezoelectric element, and effectively prevent short-circuiting between the external electrode and the internal electrode while improving conversion efficiency between the voltage and the flexural vibration in the piezoelectric element.

The insulating film is preferably configured to cover the internal-electrode-terminal facing area and also an area of the internal-electrode-side gap adjacent to the internal-electrode-terminal facing area.

The first conductive bonding material is preferably provided in such a way as to integrally cover at least a part of the lower electrode terminal and at least a part of the lower-electrode-terminal facing area of the upper electrode facing the lower electrode terminal via or through the lower-electrode-side gap.

One embodiment of the piezoelectric element assembly in accordance with the present invention may include a rigid substrate provided with a plurality of opening portions penetrating between an upper surface and a lower surface, a flexible resin film fixed to the upper surface of the substrate in such a way as to cover the plurality of opening portions, the plurality of piezoelectric elements fixed to the flexible resin film in such a way as to overlap the plurality of opening portions in plan view, a lower sealing plate that includes a central opening of a size that integrally surrounds all of the plurality of opening portions in plan view, and is fixed to an upper surface of the flexible resin film in such a way that the central opening surrounds all of the plurality of opening portions, and a wiring structure fixed to an upper surface of the lower sealing plate.

The wiring structure may include an insulating base layer supporting the first and second wirings, and an insulating cover layer covering at least parts of the first and second wirings from a side opposite to the base layer.

The base layer and the cover layer each may be configured to include a plurality of piezoelectric element overlapping portions that partially overlap the plurality of piezoelectric elements in plan view, respectively, and a tip end portion that integrally holds the plurality of piezoelectric element overlapping portions.

The piezoelectric element overlapping portion of a piezoelectric-element-side insulating layer out of the base layer and the cover layer, which is located on a side facing the piezoelectric element, is configured to include an external-electrode tab area that overlaps, in plan view, an area integrally surrounding at least a part of the lower electrode terminal and at least a part of the lower-electrode-terminal facing area and is provided with an external-electrode connection opening, and an internal-electrode tab area that overlaps, in plan view, an area surrounding at least a part of the internal electrode terminal and that is provided with an internal-electrode connection opening.

The first wiring is configured to have a portion extending across the external-electrode connection opening, and the second wiring is configured to have a portion extending across the internal-electrode connection opening. The wiring structure is fixed to an upper surface of the lower sealing plate in a state that the external-electrode connection opening overlaps, in plan view, the area that integrally includes at least a part of the lower electrode terminal and at least a part of the lower-electrode facing area, and the internal-electrode connection opening overlaps, in plan view, at least a part of the internal electrode terminal.

The portion of the first wiring extending across the external-electrode connection opening is bonded to the first conductive bonding material, and the portion of the second wiring extending across the internal-electrode connection opening is bonded to the second conductive bonding material.

In a preferable configuration, the piezoelectric element overlapping portion of an insulating layer out of the base layer and the cover layer, which is located on a side away from the piezoelectric element, may include an external-electrode tab area that overlaps, in plan view, an area integrally surrounding at least part of the lower electrode terminal and at least part of the lower-electrode-terminal facing area and is provided with an access opening, and an internal-electrode tab area that overlaps, in plan view, at least part of the internal electrode terminal and is provided with a second access opening.

In order to achieve the object, the present invention also provides a manufacturing method of a piezoelectric element assembly including a laminated piezoelectric element and a wiring structure including first and second wirings that are electrically connected to external and internal electrodes of the piezoelectric element, respectively, wherein the piezoelectric element includes a piezoelectric element main body made of a piezoelectric material, upper and lower electrodes that are arranged on upper and lower surfaces of the piezoelectric element main body, respectively and form the external electrode, an internal electrode that divides the piezoelectric element main body into upper and lower sides in the thickness direction, a lower electrode connector that has a base end side electrically connected to the lower electrode and a tip end side arranged on the upper surface of the piezoelectric element main body in a state of having a lower-electrode-side gap with respect to the upper electrode so as to form a lower electrode terminal, and an internal electrode connector that has a base end side electrically connected to the internal electrode and a tip end side arranged on the upper surface of the piezoelectric element main body in a state of having an internal-electrode-side gap with respect to the upper electrode so as to form an internal electrode terminal, the manufacturing method including: an insulating film coating step of covering at least an internal-electrode-terminal facing area of the upper electrode facing the internal electrode terminal via or through the internal-electrode-side gap with an insulating film; a step of applying a first conductive bonding material in such a way as to integrally cover at least a part of the lower electrode terminal and at least a part of the lower-electrode facing area, and applying a second conductive bonding material in such a way as to cover at least a part of the internal electrode terminal; a step of setting the wiring structure in such a way that a part of the first wiring comes into contact with the first conductive bonding material and a part of the second wiring comes into contact with the second conductive bonding material; a fixing step of fixing the part of the first wiring and the first conductive bonding material to each other and fixing the part of the second wiring and the second conductive bonding material to each other.

The insulating film coating step is preferably configured to cover, in addition to the internal-electrode-terminal facing area, an area of the internal-electrode-side gap adjacent to the internal-electrode-terminal facing area.

For example, the insulating film coating step is configured to apply a thermosetting insulating resin to an area to be covered with the insulating film, and then cure the thermosetting insulating resin.

In one embodiment, the first and second conductive bonding materials are a thermosetting conductive adhesive.

In this case, the fixing step is configured to heat and curing the first and second conductive bonding materials of the thermosetting conductive adhesive.

In another embodiment, the first and second conductive bonding materials are cream solder.

In this case, the fixing step is configured to heat and melt the first and second conductive bonding materials of cream solder and then lower a temperature to solidify the first and second conductive bonding materials.

### BRIEF DESCRIPTION OF THE DRAWINGS

FIG. 1 is a plan view of an ultrasonic transducer to which a piezoelectric element assembly according to one embodiment of the present invention is applied.

FIG. 2 is a partial vertical sectional front view of the ultrasonic transducer taken along the line II-II in FIG. 1.

FIG. 3 is a cross-sectional view taken along the line III-III in FIG. 2.

FIG. 4 is an enlarged view of a portion IV in FIG. 3.

FIGS. 5A to 5D are plan views of a rigid substrate, a flexible resin film, a plurality of piezoelectric elements and a lower sealing plate, respectively, which are components of the ultrasonic transducer, and are laminated from a lower side to an upper side in this order on the basis of the state shown in FIG. 2.

FIGS. 6A to 6E are plan views of a cover layer, first and second wirings, base layer, an intermediate portion of the first wiring and a back-surface-side cover layer of a wiring structure that is a component of the piezoelectric element assembly, respectively, and are laminated from a lower side to an upper side in this order on the basis of the state shown in FIG. 2.

FIG. 7A is a plan view of the piezoelectric element that is a component of the piezoelectric element assembly, and FIG. 7B is a cross-sectional view taken along line the VII-VII in FIG. 7A.

FIG. 8 is a plan view of the wiring structure in a state that a part of its components is omitted.

FIG. 9 is a bottom view of the wiring structure in a state that a part of its components is omitted.

FIGS. 10A to 10C are plan views of an upper sealing plate, a sound absorbing member and a reinforcing plate, respectively, which are components of the ultrasonic transducer, and are laminated from a lower side to an upper side in this order on the basis of the state shown in FIG. 2.

FIG. 11 is a plan view of another piezoelectric element capable of being applied to the piezoelectric element assembly.

### EMBODIMENT FOR CARRYING OUT THE INVENTION

Hereinafter, an embodiment of a piezoelectric element assembly according to the present invention is described with reference to the accompanying drawings.

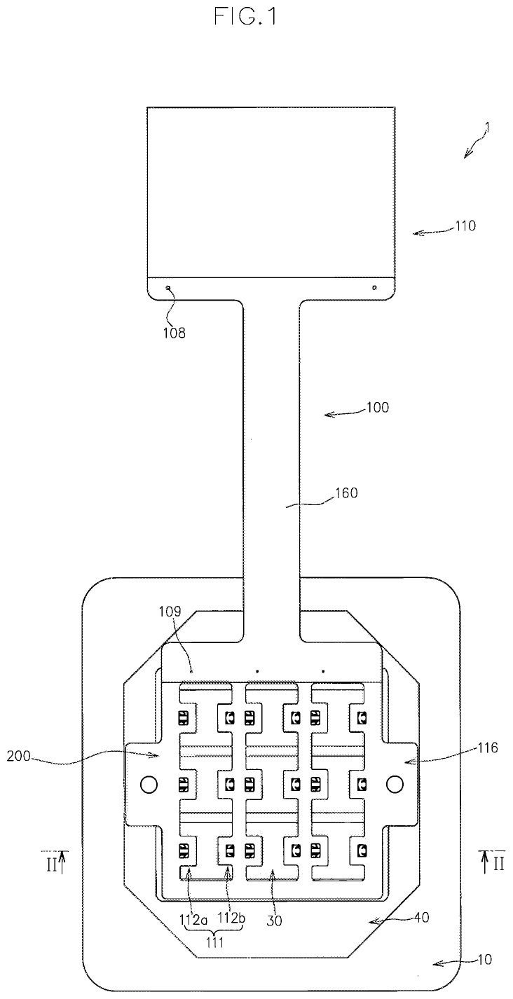

FIG. 1 illustrates a plan view of an ultrasonic transducer 1 to which a piezoelectric element assembly 200 according to the present embodiment is applied.

Note that, in FIG. 1, for easy understanding, some of the constituent members of the ultrasonic transducer 1 are omitted.

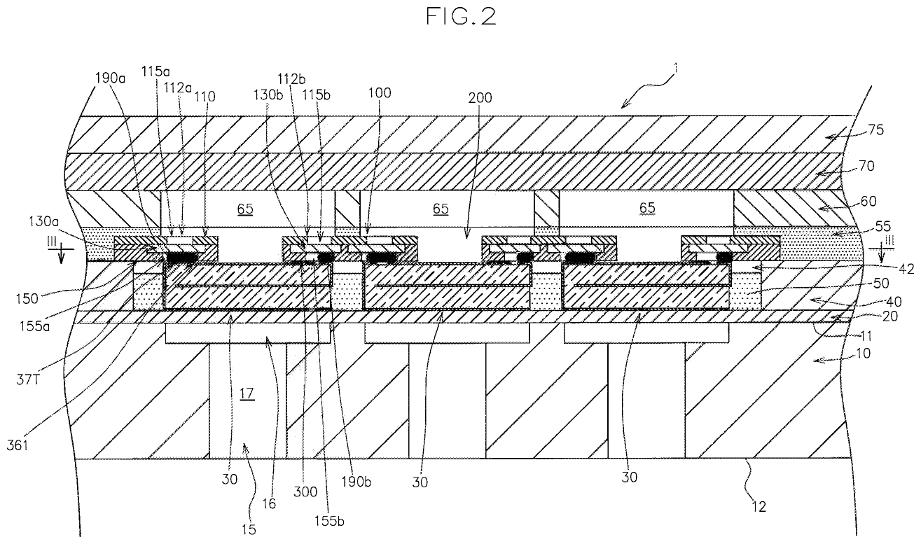

FIG. 2 illustrates a partial vertical sectional front view of the ultrasonic transducer 1 taken along the line II-II in FIG. 1.

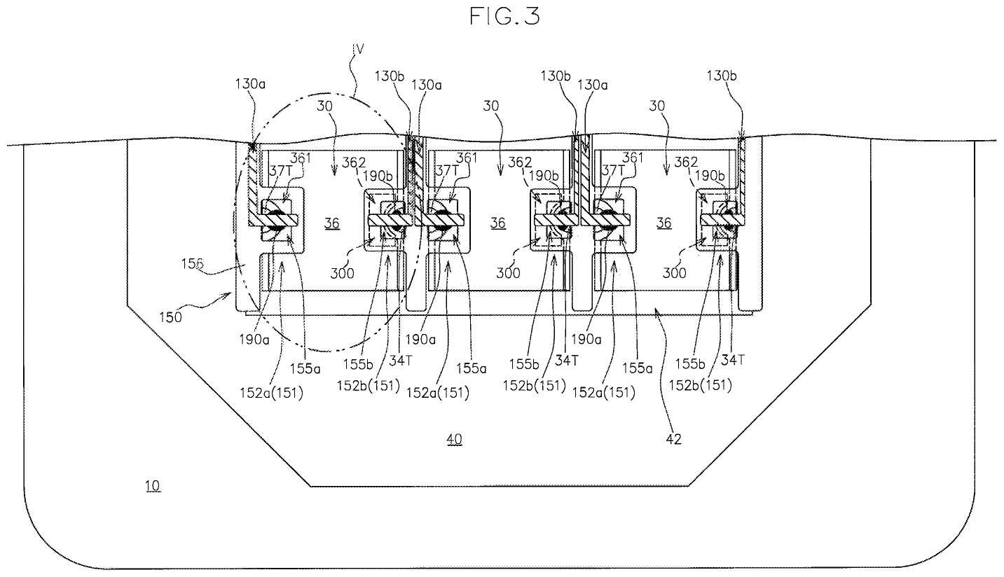

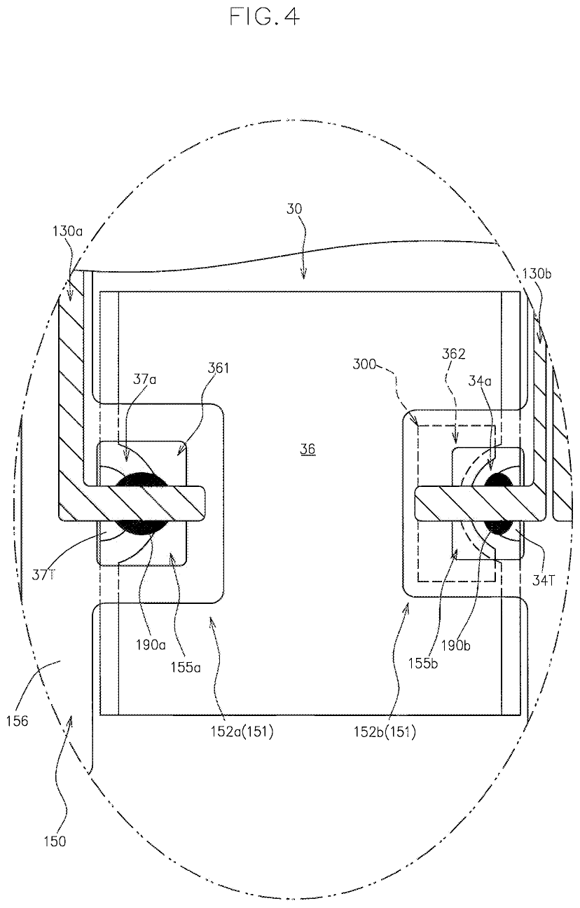

Further, FIG. 3 illustrates a cross-sectional view taken along the line III-III in FIG. 2, and FIG. 4 illustrates an enlarged view of a portion IV in FIG. 3.

The ultrasonic transducer 1 includes a rigid substrate 10, a flexible resin film 20, a plurality of piezoelectric elements 30, a lower sealing plate 40, a wiring structure 100, an upper sealing plate 60, a sound absorbing member 70, and a reinforcing plate 75 in order from the bottom to the top with reference to the cross-sectional view in FIG. 2.

Among the constituent members, the plurality of piezoelectric elements 30 and the wiring structure 100 form the piezoelectric element assembly 200.

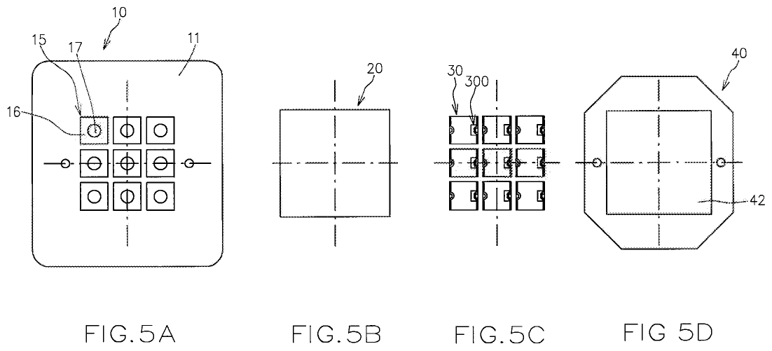

FIGS. 5A to 5D illustrate plan views of the rigid substrate 10, the flexible resin film 20, the plurality of piezoelectric elements 30, and the lower sealing plate 40, respectively.

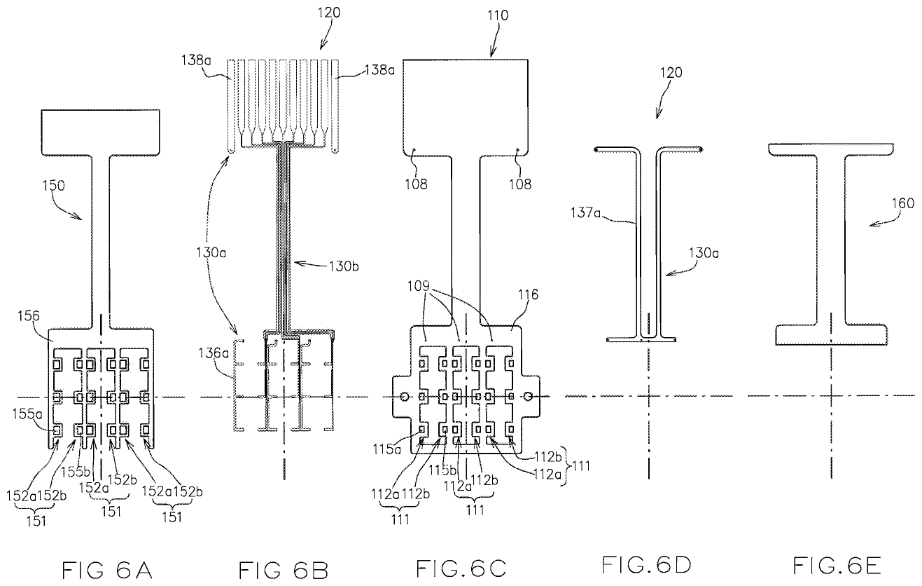

In addition, FIGS. 6A to 6E illustrate plan views of the wiring structure 100 for each constituent member.

Note that, in FIGS. 5A to 5D and FIGS. 6A to 6E, centerlines are drawn at the same position in plan view in order to facilitate understanding of a relative positional relationship between the constituent members.

The rigid substrate 10 is formed of, for example, a metal substrate such as stainless steel having a thickness of 0.1 mm to 0.4 mm, carbon fiber reinforced plastics, ceramics, and the like.

As illustrated in FIG. 2 and FIG. 5A, the rigid substrate 10 is provided with a plurality of opening portions 15 penetrating between an upper surface 11 and a lower surface 12.

The opening portion 15 has a cavity portion 16 opened to the upper surface 11 of the rigid substrate 10, and a waveguide 17 having one end opened to a bottom surface of the cavity portion 16, and the other end opened to the lower surface 12 of the rigid substrate 10.

The cavity portion 16 has the same shape as the piezoelectric element 30 in plan view.

In the present embodiment, the piezoelectric element 30 has a rectangular shape in plan view, and therefore, the cavity portion 16 also has a rectangular shape in plan view.

The opening width of the cavity portion 16 is set in such a way that a periphery of the piezoelectric element 30 overlaps the upper surface 11 of the rigid substrate 10 in plan view in a state where the piezoelectric element 30 is placed via the flexible resin film 20.

The waveguide 17 has an opening width smaller than that of the cavity portion 16.

In the present embodiment, the waveguide 17 has a circular shape in plan view.

In the present embodiment, as illustrated in FIG. 5A, the rigid substrate 10 is provided with the 3×3=nine opening portions 15, and the nine piezoelectric elements 30 are arranged in such a way as to overlap the nine opening portions 15 in plan view, respectively, in a state of sandwiching the flexible resin film 20.

That is, in the ultrasonic transducer 1, the nine piezoelectric elements 30, each of which acts as a vibrating body, are arranged in a pattern of 3×3.

For example, in order to sharpen directivity of a radiated sound wave of the ultrasonic transducer 1, and increase an intensity of the radiated sound wave, vibrating bodies (piezoelectric elements 30) of the number more than 3×3 can be arranged.

The flexible resin film 20 is fixed to the upper surface 11 of the substrate 10 in such a way as to cover the plurality of opening portions 15.

The flexible resin film 20 is formed of, for example, an insulating resin such as polyimide having a thickness of 20 μm to 100 μm.

The flexible resin film 20 is fixed to the rigid substrate 10 by various methods such as an adhesive or thermocompression bonding.

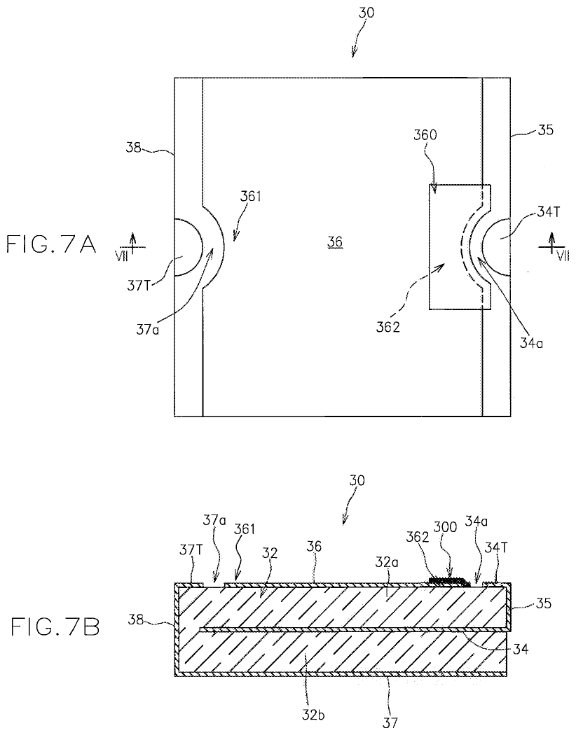

FIG. 7A illustrates a plan view of the piezoelectric element 30, and FIG. 7B illustrates a cross-sectional view taken along line the VII-VII in FIG. 7A.

The piezoelectric element 30 is fixed to an upper surface of the flexible resin film 20 in such a way that a middle portion thereof in plan view overlaps the corresponding opening portion 15 (cavity portion 16), and a peripheral portion thereof in plan view overlaps a portion of the rigid substrate 10 surrounding the corresponding opening portion 15 (cavity portion 16).

The piezoelectric element 30 is of a laminated type.

Specifically, the piezoelectric element 30 includes: a piezoelectric element main body 32 made of a piezoelectric material such as lead zirconate titanate (PZT); an internal electrode 34 for dividing the piezoelectric element main body 32 into a first piezoelectric portion 32a on an upper side and a second piezoelectric portion 32b on a lower side in the thickness direction; an upper electrode 36 fixed to a part of an upper surface of the first piezoelectric portion 32a, a lower electrode 37 fixed to a lower surface of the second piezoelectric portion 32b; an internal electrode connector 35 having a base end side electrically connected to the internal electrode 34 and a tip end side forming an internal electrode terminal 34T that is arranged on the upper surface of the piezoelectric element main body 32 in a state of having an internal-electrode-side gap 34a with respect to the upper electrode 36; and a lower electrode connector 38 having a base end side electrically connected to the lower electrode 37 and a tip end side that is arranged on the upper surface of the piezoelectric element main body 32 in a state of having a lower-electrode-side gap 37a with respect to the upper electrode 36, the tip end side forming a lower electrode terminal 37T.

In a case where the piezoelectric element 30 is used as a vibrating body of the aerial ultrasonic transducer 1, and a driving voltage applied to the piezoelectric element 30 is set to have a frequency of 40 kHz, the piezoelectric element 30 may be set to have a resonance frequency of about 70 kHz and also have a quadrangular shape with one side of 3.0 mm in plan view.

In this case, a layer thickness of the first and second piezoelectric portions 32a and 32b may be 0.1 mm to 0.2 mm.

The upper electrode 36, the lower electrode 37, and the internal electrode 34 may be formed of a metal film such as Au, AgPd, or Pt having a thickness of about 1 μm to 10 μm.

In the piezoelectric element 30, the upper electrode 36 and the lower electrode 37 form an external electrode, and the piezoelectric element 30 is configured to expand and contract, when a voltage is applied between the external electrode and the internal electrode 34.

That is, the first and second piezoelectric portions 32a and 32b have the same polarization direction in the thickness direction, whereby electric fields in opposite directions are applied to the first and second piezoelectric portions 32a and 32b by applying a predetermined voltage between the external electrode (the upper electrode 36 and the lower electrode 37) and the internal electrode 34 at predetermined frequency.

Note that, the upper electrode 36 and the lower electrode 37 are insulated from each other, and therefore, the polarization directions of the first and second piezoelectric portions 32a and 32b can be made the same by applying a voltage between the upper electrode 36 and the lower electrode 37, when the piezoelectric element 30 is produced.

In the piezoelectric element 30 having a configuration as described above, all of electrical connection of wirings (a first wiring 130a in the wiring structure 100 in the present embodiment) to be connected to the external electrode (the upper electrode 36 and the lower electrode 37) to the upper electrode 36 and the lower electrode 37, and electrical connection of wirings (a second wiring 130b in the wiring structure 100 in the present embodiment) to be connected to the internal electrode 34 to the internal electrode 34 can be performed on an upper surface of the piezoelectric element 30 on one side in the thickness direction.

That is, in the piezoelectric element 30, as described above, the lower electrode terminal 37T is provided on an upper surface of the piezoelectric element main body 32 in a state of being away from the upper electrode 36 via or through the lower-electrode-side gap 37a, and the internal electrode terminal 34T is provided on the upper surface of the piezoelectric element main body 32 in a state of being away from the upper electrode 36 via or through the internal-electrode-side gap 34a.

Therefore, as illustrated in FIG. 4, by providing a first conductive bonding material 190a in such a way as to integrally cover at least a part of the lower electrode terminal 37T and at least a part of the lower-electrode-terminal facing area 361 of the upper electrode 36 facing the lower electrode terminal 37T via or through the lower-electrode-side gap 37a, and then fixing the wiring (the first wiring 130a in the present embodiment) to be connected to the external electrode to the first conductive bonding material 190a, while providing a second conductive bonding material 190b in such a way as to cover at least a part of the internal electrode terminal 34T, and then fixing the wiring (the second wiring 130b in the present embodiment) to be connected to the internal electrode 34 to the second conductive bonding material 190b, electrical connection of the wiring (the first wiring 130a in the present embodiment) to be connected with respect to the external electrode and the external electrode, and electrical connection of the wiring (the second wiring 130b in the present embodiment) to be connected to the internal electrode 34 with respect to the internal electrode 34 can be performed on an upper surface of the piezoelectric element 30 on one side in the thickness direction.

As the first and second conductive bonding materials 190a and 190b, for example, a conductive adhesive or cream solder can be used.

Herein, in the present embodiment, as illustrated in FIGS. 4 and 7 and the like, at least an internal-electrode-terminal facing area 362 of the upper electrode 36 facing the internal electrode terminal 34T via or through the internal-electrode-side gap 34a is covered with an insulating film 300.

The insulating film 300 may be, for example, an insulator such as a polyimide resin, a silicone resin, an epoxy resin, or ceramics having a thickness of several μm to several tens of μm.

According to a configuration as described above, it is possible to advantageously prevent short-circuiting between the external electrode (the upper electrode 36) and the internal electrode 34, while improving conversion efficiency between the voltage and the flexural vibration in the piezoelectric element 30 as much as possible.

That is, in order to improve conversion efficiency between the voltage and the flexural vibration of the piezoelectric element 30, it is necessary to increase the facing area of the external electrode and the internal electrode 34, that is, the facing area of the upper electrode 36 and the internal electrode 34, and the facing area of the internal electrode 34 and the lower electrode 37 as much as possible. Therefore, an increase in the facing area of the upper electrode 36 and the internal electrode 34 can be achieved by increasing the area of the upper electrode 36 as much as possible.

However, an increase in the area of the upper electrode 36 leads to narrowing of the internal-electrode-side gap 34a, and the risk of contact of the second conductive bonding material 190b with the upper electrode 36 increases due to a variation in the application amount and a variation in the application position of the second conductive bonding material 190b to be provided on the internal electrode terminal 34T. This leads to lowering in the yield due to short-circuiting between the external electrode (the upper electrode 36) and the internal electrode 34, or lowering in the efficiency of an application operation of the second conductive bonding material 190b.

In this regard, in the present embodiment, as described above, the internal-electrode-terminal facing area 362 of the upper electrode 36 is covered with the insulating film 300.

Therefore, even if the area of the upper electrode 36 is increased to improve conversion efficiency of the piezoelectric element 30, which may narrow the internal-electrode-side gap 34a, short-circuiting between the upper electrode 36 (i.e., the external electrode) and the internal electrode 34 due to contact of the second conductive bonding material 190b with the upper electrode 36 can be advantageously prevented.

Further, even in a case where the second conductive bonding material 190b does not come into contact with the upper electrode 36 during an application operation of the second conductive bonding material 190b, narrowing of the internal-electrode-side gap 34a may cause a short circuit failure due to ion migration under the use environment conditions of the piezoelectric element 30 such as high temperature and high humidity. However, in the present embodiment, ion migration can be advantageously prevented.

As illustrated in FIG. 7A, in the present embodiment, the insulating film 300 covers not only the internal-electrode-terminal facing area 362 but also an area of the internal-electrode-side gap 34a adjacent to the internal-electrode-terminal facing area 362, whereby contact of the second conductive bonding material 190b with the upper electrode 36 is securely prevented.

The insulating film 300 may be configured in such a way as to cover the upper electrode 36 beyond the internal-electrode-terminal facing area 362, but is configured not to cover at least the lower-electrode-terminal facing area 361.

This is because electrical connection of the lower electrode terminal 37T and the upper electrode 36 (the lower-electrode-terminal facing area 361) to the first wiring 130a by the first conductive bonding material 190a is made possible.

The wiring structure 100 is configured to transmit an applied voltage, which is supplied from the outside, to the plurality of piezoelectric elements 30.

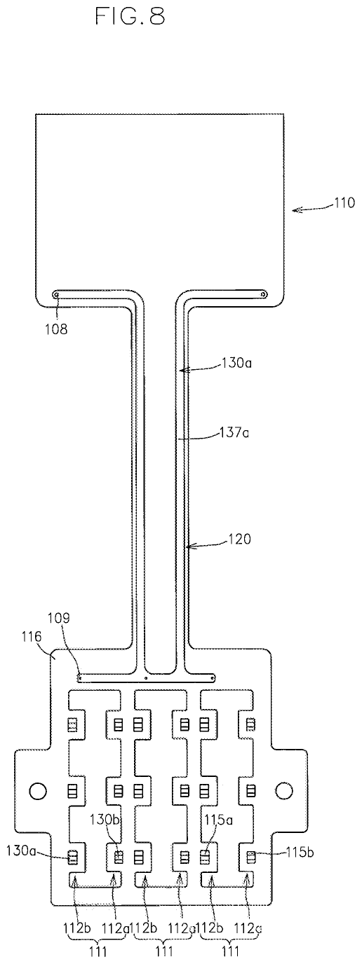

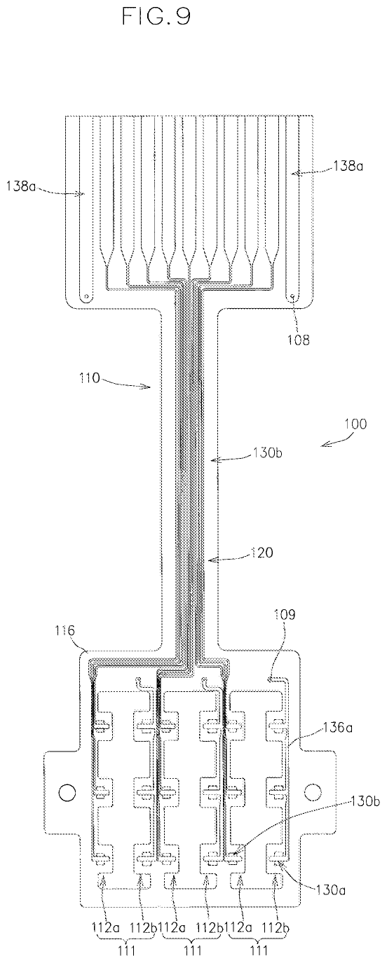

FIGS. 8 and 9 respectively illustrate a plan view (a view seen from the side opposite to or away from the piezoelectric element 30) and a bottom view (a view seen from the side of the piezoelectric element 30) of the wiring structure 100.

Note that, for easy understanding, a cover layer 150 described below is not illustrated in FIGS. 8 and 9.

As illustrated in FIGS. 6, 8, 9, and the like, the wiring structure 100 includes an insulating base layer 110, a conductive layer 120 including the first and second wirings 130a and 130b fixed to the base layer 110, and the insulating cover layer 150 for covering at least a part of the conductive layer 120 from a side opposite to or away from the base layer 110.

The base layer 110 and the cover layer 150 are formed of, for example, an insulating resin such as polyimide.

As illustrated in FIG. 8, the base layer 110 includes a plurality of base-side piezoelectric element overlapping portions 111 that partially overlap the plurality of piezoelectric elements 30 in plan view, respectively, and a base-side tip end portion 116 that integrally holds the plurality of base-side piezoelectric element overlapping portions 111.

As described above, the ultrasonic transducer 1 includes the nine (first to ninth) piezoelectric elements 30. Therefore, the base layer 110 includes the nine base-side piezoelectric element overlapping portions 111 corresponding to the nine piezoelectric elements 30, respectively.

Similarly, as illustrated in FIG. 6A, the cover layer 150 includes a plurality of cover-side piezoelectric element overlapping portions 151 that partially overlap the plurality of piezoelectric elements 30 in plan view, respectively, and a cover-side tip portion 156 that integrally holds the plurality of cover-side piezoelectric element overlapping portions 151.

The cover-side piezoelectric element overlapping portions 151 are also provided by the number corresponding to the number of the plurality of piezoelectric elements.

The piezoelectric element overlapping portion 151 of a piezoelectric-element-side insulating layer (the cover layer 150 (see FIG. 2) in the present embodiment) out of the base layer 110 and the cover layer 150, which is located on a side facing the piezoelectric element, includes an external-electrode tab area 152a that overlaps, in plan view, an area integrally surrounding at least a part of the lower electrode terminal 37T and at least a part of the lower-electrode-terminal facing area 361, and an internal-electrode tab area 152b that overlaps, in plan view, an area surrounding at least a part of the internal electrode terminal 34T.

As illustrated in FIGS. 2, 4, and 6, an external-electrode connection opening 155a and an internal-electrode connection opening 155b are provided in the external-electrode tab area 152a and the internal-electrode tab area 152b, respectively.

The first and second wirings 130a and 130b are formed of a conductive metal, for example, such as Cu.

The first and second wirings 130a and 130b can be formed by etching and removing an unnecessary portion of a Cu foil having a thickness of about 12 to 25 μm and being laminated on the base layer 110.

Preferably, Ni/Au-plating may be performed on an exposed portion of the first and second wirings 130a and 130b that forms Cu.

As illustrated in FIG. 4, a part of the first wiring 130a extends across or straddles the external-electrode connection opening 155a, and a part of the second wiring 130b extends across or straddles the internal-electrode connection opening 155b.

The wiring structure 100 is fixed to an upper surface of the lower sealing plate 40 in a state that the external-electrode connection opening 155a overlaps the area that integrally includes at least a part of the lower electrode terminal 37T and at least a part of the lower-electrode facing area 361 in plan view, and the internal-electrode connection opening 155b overlaps at least a part of the internal electrode terminal 34T in plan view, and a portion of the first wiring 130a extending across the external-electrode connection opening 155a is bonded to the first conductive bonding material 190a, and a portion of the second wiring 130b extending across the internal-electrode connection opening 155b is bonded to the second conductive bonding material 190b.

In the present embodiment, the piezoelectric element overlapping portion 111 of the insulating layer (the base layer 110 (see FIG. 2) in the present embodiment) out of the base layer 110 and the cover layer 150, which is located on a side away from the piezoelectric element 30, also includes an external-electrode tab area 112a that overlaps, in plan view, an area integrally surrounding at least part of the lower electrode terminal 37T and at least part of the lower-electrode-terminal facing area 361, and an internal-electrode tab area 112b that overlaps, in plan view, at least part of the internal electrode terminal 34T, similarly to the piezoelectric-element-side insulating layer (the cover layer 150 in the present embodiment).

First and second access openings 115a and 115b are provided in the external-electrode tab area 112a and the internal-electrode tab area 112b, respectively.

Note that, in the present embodiment, the first wiring 130a is a common wiring that is integrally and electrically connected to external electrodes of the plurality of piezoelectric elements 30, and the second wiring 130b is an individual wiring that is individually and electrically connected to each of the internal electrodes 34 of the plurality of piezoelectric elements 30.

The first wiring 130a is disposed on a surface of the base layer 110 on a side close to the piezoelectric element at a tip end side 136a to be electrically connected to the external electrodes of the plurality of piezoelectric elements 30, and a base end side 138a forming a connection terminal to the outside, and is disposed on a surface of the base layer 110 on a side opposite to or away from the piezoelectric element 30 at an intermediate portion 137a that interconnects the tip end 136a and the base end 138a.

The tip end side 136a and the intermediate portion 137a of the first wiring 130a are electrically connected to each other via a through-hole 109 formed in the base layer 110, and the intermediate portion 137a and the base end side 138a of the first wiring 130a are electrically connected to each other via a through-hole 108 formed in the base layer 110.

A portion of the first wiring 130a disposed on a surface of the base layer 110 on a side opposite to or away from the piezoelectric element 30 is covered with a back-surface-side cover layer 160 (see FIG. 6(e)).

The second wiring 130b is disposed on a surface of the base layer 110 on a side close to the piezoelectric element over the entire area.

As described above, in the ultrasonic transducer 1, as illustrated in FIG. 2, the wiring structure 100 is fixed to the lower sealing body 40 in a state that the cover layer 150 faces the piezoelectric element 30, and the base layer 110 is located on a side opposite to or away from the piezoelectric element 30 with respect to the conductive layer 120.

As illustrated in FIG. 2 and FIG. 5(d), the lower sealing plate 40 includes a central opening 42 of a size that integrally surrounds the plurality of (nine in the present embodiment) opening portions 15 in the rigid substrate 10, and is fixed to the upper surface of the flexible resin film 20 in such a way that the central opening 42 integrally surrounds the plurality of opening portions 15 in plan view.

As illustrated in FIG. 2, the lower sealing plate 40 has substantially the same thickness as the piezoelectric element 30, and is fixed to the upper surface of the flexible resin film 20 by an adhesive, thermocompression bonding, or the like.

The lower sealing plate 40 is preferably formed of a metal such as stainless steel, carbon fiber reinforced plastics, ceramics, and the like.

The lower sealing plate 40 seals the side of a piezoelectric element group constituted of the plurality of piezoelectric elements 30, and acts as a mount base to which the wiring structure 100 is fixed.

In the present embodiment, as illustrated in FIG. 2, a flexible resin 50 is filled in a side portion of each of the plurality of piezoelectric elements 30 within a space surrounded by the central opening 42 of the lower sealing plate 40.

The flexible resin 50 is, for example, silicone.

By providing the flexible resin 50, it is possible to advantageously block an external influence on the plurality of piezoelectric elements 30.

Further, vibration damping of the piezoelectric element 30 can be increased, and reverberation of a sound wave generated in a burst manner by the plurality of piezoelectric elements 30 can be suppressed, which can widen a distance detectable range of an object by a reflected wave as much as possible.

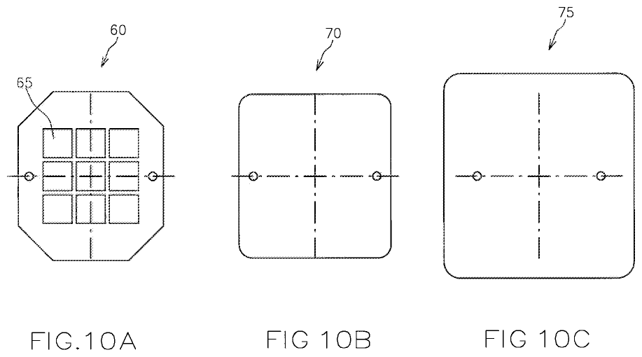

FIGS. 10A to 10C illustrate plan views of the upper sealing plate 60, the sound absorbing member 70, and the reinforcing plate 75, respectively.

Note that, in FIGS. 10A to 10C, in order to facilitate understanding of a relative positional relationship between the component members, centerlines are drawn at the same position in plan view as in the case of FIGS. 5A to 5D and FIGS. 6A to 6E.

As illustrated in FIG. 2, the upper sealing plate 60 is fixed to an upper surface of the lower sealing plate 40 and the wiring assembly 100 via a flexible resin 55.

As illustrated in FIGS. 2 and 10A, the upper sealing plate 60 includes a plurality of (nine in the present embodiment) opening portions 65 corresponding to the plurality of piezoelectric elements 30, respectively.

By providing the upper sealing plate 60, it is possible to support and stabilize the wiring structure 100, while preventing an influence on a flexural vibration operation of the vibrating body as much as possible.

The upper sealing plate 60 is formed of, for example, a metal such as stainless steel having a thickness of 0.1 mm to 0.3 mm, carbon fiber reinforced plastics, ceramics, and the like.

The sound absorbing member 70 is fixed to an upper surface of the upper sealing plate 60 by adhesion or the like in such a way as to cover the plurality of opening portions 65 of the upper sealing plate 60.

The sound absorbing member 70 is formed of, for example, a silicone resin having a thickness of about 0.3 mm to 1.5 mm or another foamable resin.

By providing the sound absorbing member 70, it is possible to effectively suppress emission of a sound wave to be generated by the piezoelectric element 30 toward the side opposite to or away from the side (the lower side in FIG. 2) to which the sound wave should be emitted.

The reinforcing plate 75 is fixed to an upper surface of the sound absorbing member 70 by adhesion or the like.

The reinforcing plate 75 is formed of, for example, a metal such as stainless steel having a thickness of about 0.2 mm to 0.5 mm, carbon fiber reinforced plastics, ceramics, and the like.

By providing the reinforcing plate 75, it is possible to prevent an external force from affecting the substrate 10 and the piezoelectric element 30 as much as possible.

Hereinafter, a manufacturing method of the ultrasonic transducer 1 is described.

The manufacturing method includes
a rigid substrate forming step of forming the rigid substrate 10 having the plurality of opening portions 15 by etching a rigid plate member;
a flexible resin film fixing step of fixing the flexible resin film 20 to an upper surface of the rigid substrate 10 by an adhesive or thermocompression bonding in such a way as to cover the plurality of opening portions 15;
a piezoelectric element fixing step of fixing the plurality of piezoelectric elements 30 to an upper surface of the flexible resin film 20 by an insulating adhesive in such a way as to overlap the plurality of opening portions 15 in plan view, respectively;
a lower sealing plate installation step of fixing the lower sealing plate 40 to the upper surface of the flexible resin 20 by an adhesive in such a way that the central opening 42 integrally surrounds the plurality of opening portions 15 in plan view;
a wiring structure preparation step of preparing the wiring structure 100;
a wiring structure fixing step of fixing the wiring structure 100 to an upper surface of the lower sealing plate 40 by an insulating adhesive in such a way that the external-electrode connection opening 155a overlaps an area integrally including at least a part of the lower electrode terminal 37T and at least a part of the lower-electrode-terminal facing area 361 in plan view, and the internal-electrode connection opening 155b overlaps at least a part of the internal electrode terminal 34T in plan view; and
an electrical connection step of electrically connecting a portion of the first wiring 130a that extends across the external-electrode connection opening 155a to the lower electrode terminal 37T and the upper electrode 36, and electrically connecting a portion of the second wiring 130b that extends across the internal-electrode connection opening 155b to the internal electrode terminal 34T.

Preferably, the manufacturing method may include a bonding step of integrally performing the wiring structure fixing step and the electrical connection step at a same time.

The bonding step includes a process of applying a thermosetting insulating adhesive to a predetermined portion on an upper surface of the lower sealing plate 40; a process of applying the first conductive bonding material 190a formed by a thermosetting conductive adhesive or cream solder by a dispenser, screen printing, transfer, or the like in such a way as to extend across at least a part of the lower electrode terminal 37T and at least a part of the lower-electrode facing area 361; a process of applying the second conductive bonding material 190b formed by a thermosetting conductive adhesive or cream solder to at least a part of the internal electrode terminal 34T by a dispenser, screen printing, transfer, or the like; a process of forming a preassembly by disposing the wiring structure 100 to a predetermined position on an upper surface of the lower sealing plate 40; and a process of curing the thermosetting insulating adhesive, and the first and second conductive bonding materials 190a and 190b by thermally treating the preassembly.

The heating temperature may be about 120° C. to 150° C. in a case where the first and second conductive bonding materials 190a and 190b are a thermosetting conductive adhesive, and may be 230° C. to 260° C. in a case where the first and second conductive bonding materials 190a and 190b are cream solder. Note that, in the case of the cream solder, the cream solder is melted by heating and solidified by lowering the temperature from the melted state.

By providing the bonding step, fixation of the wiring structure 100 and the lower sealing plate 40, and electrical connection of the wiring structure 100 and the piezoelectric element 30 can be performed at the same time, which can improve efficiency.

In a case where the wiring structure fixing step is performed first, and then, the electrical connection step is performed, the electrical connection step is configured to include: a process of applying the first conductive bonding material 190a via the first access opening 115a and the external-electrode connection opening 155a in such a way that the first conductive bonding material 190a integrally covers at least a part of the lower electrode terminal 37T and at least a part of the lower-electrode-terminal facing area 361; a process of applying the second conductive bonding material 190b via the second access opening 115b and the internal-electrode connection opening 155b in such a way that the second conductive bonding material 190b covers at least a part of the internal electrode terminal 34T; and a process of curing the first and second conductive bonding materials 190a and 190b.

In the manufacturing method, the insulating film 300 may be provided on the piezoelectric element 30 at any timing before the process of applying the second conductive bonding material 190b.

When an epoxy resin or a silicone resin is used as the insulating film 300, the insulating film 300 is formed by applying monomer by a dispenser, screen printing, or the like, and then heating and curing the monomer at, for example, about 100° C. to 150° C.

The manufacturing method further includes, after the lower sealing plate installation step and before the wiring structure fixing step, a sealing resin applying step of pouring a thermosetting sealing resin such as a liquid silicone resin into a side portion of the plurality of piezoelectric elements 30 within a space defined by the central opening 42 of the lower sealing plate 40, and curing the thermosetting sealing resin by heating at, for example, about 100° C. to 150° C. for several tens of minutes.

The manufacturing method further includes an upper sealing plate installation step of installing the upper sealing plate 60 after the electrical connection step.

The upper sealing plate installation step includes a process of applying a thermosetting flexible resin such as a silicone resin to an upper surface of the wiring structure 100, a process of arranging the upper sealing plate 60 on the flexible resin, and a process of curing the flexible resin by heating at, for example, about 100° C. to 150° C. for several tens of minutes.

The manufacturing method further includes a sound absorbing member installation step and a reinforcing plate installation step after the upper sealing plate installation step.

The sound absorbing member installation step includes a process of applying a thermosetting insulating adhesive to an upper surface of the upper sealing plate 60, a process of disposing the sound absorbing member 70 such as a silicone resin or another foamable resin on the thermosetting insulating adhesive, and a process of curing the thermosetting insulating adhesive by heating at, for example, about 120° C. to 150° C. for several tens of minutes.

The reinforcing plate installation step includes a process of applying a thermosetting insulating adhesive to an upper surface of the sound absorbing member 70, a process of disposing the reinforcing plate 75 on the thermosetting insulating adhesive, and a process of curing the thermosetting insulating adhesive by heating at, for example, about 120° C. to 150° C. for several tens of minutes.

Note that in the present embodiment, as illustrated in FIG. 7A, the lower electrode terminal 37T and the internal electrode terminal 34T are respectively disposed at a midway part of one side and the other side forming an outer shape of the piezoelectric element 30 in plan view. However, the present invention is not limited thereto.

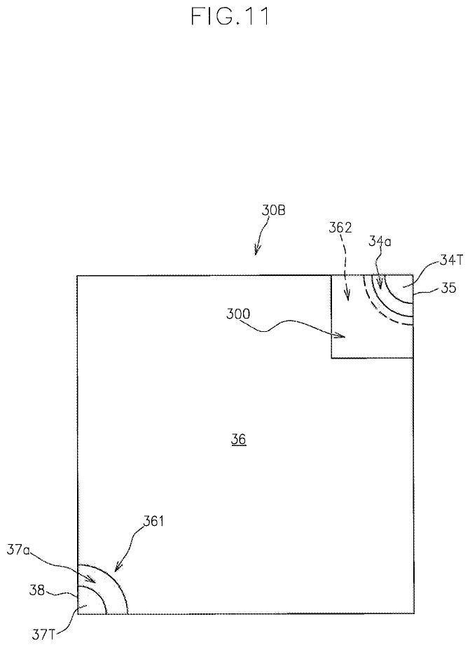

FIG. 11 illustrates a plan view of another piezoelectric element 30B to which the present invention can be applied.

In the piezoelectric elements 30B, the lower electrode terminal 37T and the internal electrode terminal 34T are disposed at respective corner portions of a rectangular shape in plan view.

### DESCRIPTION OF THE REFERENCE NUMERALS

10 substrate
15 opening portion
20 flexible resin film
30 piezoelectric element
32 piezoelectric element main body
34 internal electrode
34a internal-electrode-side gap
34T internal electrode terminal
35 internal electrode connector
36 upper electrode (external electrode)
37 lower electrode (external electrode)
37a lower-electrode-side gap
37T lower electrode terminal
38 lower electrode connector
40 lower sealing plate
42 central opening
100 wiring structure
108, 109 through-hole
110 insulating base layer
111 base-side piezoelectric element overlapping portion
112a external-electrode tab area of base layer
112b internal-electrode tab area of base layer
115a first access opening
115b second access opening
116 base-side tip end portion
130a first wiring
130b second wiring
150 insulating cover layer
151 cover-side piezoelectric element overlapping portion
152a external-electrode tab area of cover layer
152b internal-electrode tab area of cover layer
155a external-electrode connection opening
155b internal-electrode connection opening
156 cover-side tip portion
190a first conductive bonding material
190b second conductive bonding material
300 insulating film
361 lower-electrode-terminal facing area
362 internal-electrode-terminal facing area

1. A piezoelectric element assembly including a laminated piezoelectric element and a wiring structure including first and second wirings that are electrically connected to external and internal electrodes of the piezoelectric element, respectively,
wherein the piezoelectric element includes a piezoelectric element main body made of a piezoelectric material, upper and lower electrodes that are arranged on upper and lower surfaces of the piezoelectric element main body, respectively and form the external electrode, an internal electrode that divides the piezoelectric element main body into upper and lower sides in the thickness direction, a lower electrode connector that has a base end side electrically connected to the lower electrode and a tip end side arranged on the upper surface of the piezoelectric element main body in a state of having a lower-electrode-side gap with respect to the upper electrode so as to form a lower electrode terminal, and an internal electrode connector that has a base end side electrically connected to the internal electrode and a tip end side arranged on the upper surface of the piezoelectric element main body in a state of having an internal-electrode-side gap with respect to the upper electrode so as to form an internal electrode terminal,
wherein the first wiring is electrically connected to the lower electrode terminal and the upper electrode via a first conductive bonding material,
wherein the second wiring is electrically connected to the internal electrode terminal via a second conductive boding material, and
wherein an internal-electrode-terminal facing area of the upper electrode facing the internal electrode terminal through the internal-electrode-side gap is covered with an insulating film.

2. The piezoelectric element assembly according to claim 1, wherein the insulating film covers, in addition to the internal-electrode-terminal facing area, an area of the internal-electrode-side gap adjacent to the internal-electrode-terminal facing area.

3. The piezoelectric element assembly according to claim 1, wherein the first conductive bonding material is provided in such a way as to integrally cover at least a part of the lower electrode terminal and at least a part of the lower-electrode-terminal facing area of the upper electrode facing the lower electrode terminal through the lower-electrode-side gap.

4. The piezoelectric element assembly of claim 1, further comprising
a rigid substrate provided with a plurality of opening portions penetrating between an upper surface and a lower surface,
a flexible resin film fixed to the upper surface of the substrate in such a way as to cover the plurality of opening portions,
the plurality of piezoelectric elements fixed to the flexible resin film in such a way as to overlap the plurality of opening portions in plan view,
a lower sealing plate that includes a central opening of a size that integrally surrounds all of the plurality of opening portions in plan view, and is fixed to an upper surface of the flexible resin film in such a way that the central opening surrounds all of the plurality of opening portions, and
a wiring structure fixed to an upper surface of the lower sealing plate.

5. The piezoelectric element assembly according to claim 4,
wherein the wiring structure includes an insulating base layer supporting the first and second wirings, and an insulating cover layer covering at least parts of the first and second wirings from a side opposite to the base layer,
wherein the base layer and the cover layer each include a plurality of piezoelectric element overlapping portions that partially overlap the plurality of piezoelectric elements in plan view, respectively, and a tip end portion that integrally holds the plurality of piezoelectric element overlapping portions,
wherein the piezoelectric element overlapping portion of a piezoelectric-element-side insulating layer out of the base layer and the cover layer, which is located on a side facing the piezoelectric element, includes an external-electrode tab area that overlaps, in plan view, an area integrally surrounding at least a part of the lower electrode terminal and at least a part of the lower-electrode-terminal facing area and is provided with an external-electrode connection opening, and an internal-electrode tab area that overlaps, in plan view, an area surrounding at least a part of the internal electrode terminal and that is provided with an internal-electrode connection opening,
wherein the first wiring has a portion extending across the external-electrode connection opening, and the second wiring has a portion extending across the internal-electrode connection opening,
wherein the wiring structure is fixed to an upper surface of the lower sealing plate in a state that the external-electrode connection opening overlaps, in plan view, the area that integrally includes at least a part of the lower electrode terminal and at least a part of the lower-electrode facing area, and the internal-electrode connection opening overlaps, in plan view, at least a part of the internal electrode terminal,
wherein the portion of the first wiring extending across the external-electrode connection opening is bonded to the first conductive bonding material, and
wherein the portion of the second wiring extending across the internal-electrode connection opening is bonded to the second conductive bonding material.

6. The piezoelectric element assembly according to claim 5, wherein the piezoelectric element overlapping portion of an insulating layer out of the base layer and the cover layer, which is located on a side away from the piezoelectric element, includes an external-electrode tab area that overlaps, in plan view, an area integrally surrounding at least part of the lower electrode terminal and at least part of the lower-electrode-terminal facing area and is provided with an access opening, and an internal-electrode tab area that overlaps, in plan view, at least part of the internal electrode terminal and is provided with a second access opening.

7. A manufacturing method of a piezoelectric element assembly including a laminated piezoelectric element and a wiring structure including first and second wirings that are electrically connected to external and internal electrodes of the piezoelectric element, respectively, wherein the piezoelectric element includes a piezoelectric element main body made of a piezoelectric material, upper and lower electrodes that are arranged on upper and lower surfaces of the piezoelectric element main body, respectively and form the external electrode, an internal electrode that divides the piezoelectric element main body into upper and lower sides in the thickness direction, a lower electrode connector that has a base end side electrically connected to the lower electrode and a tip end side arranged on the upper surface of the piezoelectric element main body in a state of having a lower-electrode-side gap with respect to the upper electrode so as to form a lower electrode terminal, and an internal electrode connector that has a base end side electrically connected to the internal electrode and a tip end side arranged on the upper surface of the piezoelectric element main body in a state of having an internal-electrode-side gap with respect to the upper electrode so as to form an internal electrode terminal, the manufacturing method comprising:
an insulating film coating step of covering at least an internal-electrode-terminal facing area of the upper electrode facing the internal electrode terminal through the internal-electrode-side gap with an insulating film;
a step of applying a first conductive bonding material in such a way as to integrally cover at least a part of the lower electrode terminal and at least a part of the lower-electrode facing area, and applying a second conductive bonding material in such a way as to cover at least a part of the internal electrode terminal;
a step of setting the wiring structure in such a way that a part of the first wiring comes into contact with the first conductive bonding material and a part of the second wiring comes into contact with the second conductive bonding material; and
a fixing step of fixing the part of the first wiring and the first conductive bonding material to each other and fixing the part of the second wiring and the second conductive bonding material to each other.

8. The manufacturing method according to claim 7, wherein the insulating film coating step is configured to cover, in addition to the internal-electrode-terminal facing area, an area of the internal-electrode-side gap adjacent to the internal-electrode-terminal facing area.

9. The manufacturing method according to claim 7, wherein the insulating film coating step is configured to apply a thermosetting insulating resin to an area to be covered with the insulating film, and then cure the thermosetting insulating resin.

10. The manufacturing method of claim 7,
wherein the first and second conductive bonding materials are a thermosetting conductive adhesive, and
wherein the fixing step is configured to heat and curing the first and second conductive bonding materials of the thermosetting conductive adhesive.

11. The manufacturing method of claim 7,
wherein the first and second conductive bonding materials are cream solder,
wherein the fixing step is configured to heat and melt the first and second conductive bonding materials of cream solder and then lower a temperature to solidify the first and second conductive bonding materials.
